(19) United States
(12) Patent Application Publication
(10) Pub. No.: US 2025/0244662 A1
(43) Pub. Date: Jul. 31, 2025

(54) PHOTOMASK PATTERN INSPECTION METHOD AND SYSTEM, AND METHOD OF MANUFACTURING DISPLAY DEVICE USING THE SAME

(71) Applicant: Samsung Display Co., LTD., Yongin-si (KR)

(72) Inventors: Chanhyeong CHO, Yongin-si (KR); Taejoon KIM, Yongin-si (KR); Soonhwan SO, Yongin-si (KR); Wonseon YU, Yongin-si (KR)

(21) Appl. No.: 19/017,217

(22) Filed: Jan. 10, 2025

(30) Foreign Application Priority Data
Jan. 30, 2024 (KR) 10-2024-0014319

(51) Int. Cl. G03F 1/84; H10K 59/12

(52) U.S. Cl. CPC G03F 1/84; H10K 59/1201

(57) ABSTRACT

A photomask pattern inspection method includes generating first result image data by performing first exposure simulation based on photomask design data, generating second result image data by performing second exposure simulation based on optical image data obtained by photographing an actual photomask, and generating inspection data for the actual photomask based on the first result image data and the second result image data.

This application claims priority to Korean Patent Application No. 10-2024-0014319, filed on Jan. 30, 2024, and all the benefits accruing therefrom under 35 U.S.C. § 119, the content of which in its entirety is herein incorporated by reference.

### BACKGROUND

### 1. Field

Embodiments relate to a photomask pattern inspection method and system, and a method of manufacturing a display device using the same, and more particularly, to a photomask pattern inspection method and system capable of rapidly inspecting a photomask pattern, and a method of manufacturing a display device using the same.

### 2. Description of the Related Art

Display devices display images by receiving information about the images. Display devices are used as displays of small-sized products such as mobile phones or displays of large-sized products such as televisions.

Circuits or wiring structures in display devices may be micro-patterns. Such micro-patterns are formed through photolithography processes and etching processes. For photolithography processes, photomasks with micro-patterns are used. Therefore, for accurate display device processing, it is desired to inspect photomask patterns during a photomask manufacturing operation.

### SUMMARY

Embodiments include a photomask pattern inspection method and system capable of rapidly inspecting a photomask pattern. However, the embodiments are only examples, and the scope of the disclosure is not limited thereby.

Additional features will be set forth in part in the description which follows and, in part, will be apparent from the description, or may be learned by practice of the presented embodiments of the disclosure.

In an embodiment of the disclosure, a photomask pattern inspection method may include generating first result image data by performing first exposure simulation based on photomask design data, generating second result image data by performing second exposure simulation based on optical image data obtained by photographing an actual photomask, and generating inspection data for the actual photomask based on the first result image data and the second result image data.

In an embodiment, the photomask design data may be design data for the actual photomask.

In an embodiment, the generating the first result image data may include generating the first result image data by performing the first exposure simulation based on pre-input exposure condition data and the photomask design data.

In an embodiment, the generating the second result image data may include generating the second result image data by performing the second exposure simulation based on the pre-input exposure condition data and the optical image data.

In an embodiment, the generating the inspection data for the actual photomask may include generating a differential image of the first result image data and the second result image data, and generating the inspection data based on the differential image.

In an embodiment, the generating the inspection data based on the differential image may include, when a characteristic value derived from the differential image is greater than a preset threshold value, defining the actual photomask as being in a defective state, and when the characteristic value is less than or equal to the preset threshold value, defining the actual photomask as being in a normal state.

In an embodiment, the generating the first result image data may include loading input exposure condition data and the photomask design data, outputting a first exposure result image by performing the first exposure simulation based on the input exposure condition data and the photomask design data, and generating the first result image data by correcting the first exposure result image.

In an embodiment, the generating the first result image data by correcting the first exposure result image may include correcting the first exposure result image into a grayscale image having a same resolution as a resolution of the second result image data.

In an embodiment, the generating the second result image data may include loading input exposure condition data and receiving the optical image data, performing a preprocessing process on the optical image data, after the preprocessing process, outputting a second exposure result image by performing the second exposure simulation based on the input exposure condition data and the optical image data, and generating the second result image data by correcting the second exposure result image.

In an embodiment, the performing the preprocessing process on the optical image data may include obtaining a contour image from the optical image data, and changing a resolution of the contour image to a resolution of the photomask design data.

In an embodiment of the disclosure, a photomask pattern inspection system may include an optical system device configured to generate optical image data for an actual photomask, and a computing device configured to generate first result image data by performing first exposure simulation based on pre-stored photomask design data, generate second result image data by performing second exposure simulation based on the optical image data, and generate inspection data for the actual photomask based on the first result image data and the second result image data.

In an embodiment, the photomask design data may be design data for the actual photomask.

In an embodiment, the computing device may be further configured to generate the first result image data by performing the first exposure simulation based on pre-input exposure condition data and the photomask design data.

In an embodiment, the computing device may be further configured to generate the second result image data by performing the second exposure simulation based on the pre-input exposure condition data and the optical image data.

In an embodiment, the computing device may be further configured to generate a differential image of the first result image data and the second result image data and generate the inspection data based on the differential image.

In an embodiment, the computing device may be further configured to define the actual photomask as being in a defective state in a case that a characteristic value derived from the differential image is greater than a preset threshold value, and define the actual photomask as being in a normal state in a case that the characteristic value is less than or equal to the preset threshold value.

In an embodiment, the computing device may be further configured to load input exposure condition data and the photomask design data, output a first exposure result image by performing the first exposure simulation based on the photomask design data, and generate the first result image data by correcting the first exposure result image.

In an embodiment, the first result image data may be corrected into a grayscale image having a same resolution as a resolution of the second result image data.

In an embodiment, the computing device may be further configured to load input exposure condition data and receive the optical image data, perform a preprocessing process on the optical image data, after the preprocessing process, output a second exposure result image by performing the second exposure simulation based on the input exposure condition data and the optical image data, and generate the second result image data by correcting the second exposure result image.

In an embodiment, the computing device may be further configured to obtain a contour image from the optical image data and change a resolution of the contour image to a resolution of the photomask design data.

In an embodiment of the disclosure, a method of manufacturing a display device may include inspecting a pattern of an actual photomask by a computing device, in a case that the pattern of the actual photomask is in a normal state, arranging the actual photomask on a target substrate, performing an exposure process on the target substrate by the actual photomask, where the inspecting the pattern of the actual photomask may include generating first result image data by performing first exposure simulation based on photomask design data, generating second result image data by performing second exposure simulation based on optical image data obtained by photographing the actual photomask; and generating inspection data for the actual photomask based on the first result image data and the second result image data.

In an embodiment, the photomask design data may be design data for the actual photomask.

In an embodiment, the generating the first result image data may include generating the first result image data by performing the first exposure simulation based on pre-input exposure condition data and the photomask design data.

In an embodiment, the generating the second result image data may include generating the second result image data by performing the second exposure simulation based on the pre-input exposure condition data and the optical image data.

In an embodiment, the generating the inspection data for the actual photomask may include generating a differential image of the first result image data and the second result image data, and generating the inspection data based on the differential image.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a flowchart schematically illustrating an embodiment of a photomask pattern inspection method;

FIG. 2 is a flowchart schematically illustrating an operation of generating first result image data by performing first exposure simulation of FIG. 1;

FIG. 3 is a flowchart schematically illustrating an operation of generating second result image data by performing second exposure simulation of FIG. 1;

FIG. 4 is a flowchart schematically illustrating an operation of FIG. 1, of generating inspection data;

FIG. 5A is a view schematically illustrating an embodiment of a photomask pattern inspection system, and FIG. 5B is a view illustrating an actual photomask disposed on target substrate;

FIG. 6 is a view illustrating an embodiment of photomask design data for performing the first exposure simulation;

FIG. 7 is a view illustrating an embodiment of a first exposure result image generated based on the photomask design data of FIG. 6;

FIG. 8 is a view illustrating an embodiment of the first result image data generated based on the first exposure result image of FIG. 7;

FIG. 9 is a view illustrating an embodiment of optical image data obtained by photographing an actual photomask for performing the second exposure simulation;

FIG. 10 is a view illustrating an embodiment of a contour image generated based on the optical image data of FIG. 9;

FIG. 11 is a view illustrating an embodiment of a second exposure result image generated based on the contour image of FIG. 10; and

FIG. 12 is a view illustrating an embodiment of the second result image data generated based on the second exposure result image of FIG. 11.

### DETAILED DESCRIPTION

Reference will now be made in detail to embodiments, embodiments of which are illustrated in the accompanying drawings, where like reference numerals refer to like elements throughout the specification. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the illustrated embodiments, and particular embodiments of the disclosure will be illustrated in the drawings and described in the detailed description section. The effect and features of the illustrated embodiments, and a method to achieve the same, will be clearer referring to the detailed descriptions below with the drawings. However, the disclosure may be implemented in various forms, not by being limited to the embodiments presented below.

Hereinafter, embodiments of the disclosure will be described in detail with reference to the accompanying drawings, and in the description with reference to the drawings, the same or corresponding components are indicated by the same reference numerals and redundant descriptions thereof are omitted.

In the following embodiment, it will be understood that when a component such as a layer, film, region, or plate is referred to as being “formed on” another layer, film, region, or plate, it may be directly or indirectly formed on the other layer, film, region, or plate. That is, for example, intervening layers, films, regions, or plates may be present. In addition, in the following embodiment, it will be understood that when a component such as a layer, film, region, or plate is referred to as being “formed under” another layer, film, region, or plate, it may be directly or indirectly formed under the other layer, film, region, or plate. That is, for example, intervening layers, films, regions, or plates may be present.

Sizes of components in the drawings may be exaggerated or reduced for convenience of explanation. In other words, since sizes and thicknesses of components in the drawings are arbitrarily illustrated for convenience of explanation, the following the disclosure is not limited thereto. That is, for convenience of explanation, sizes, thicknesses, and ratios of components in the drawings may be exaggerated and/or simplified for clarity. Accordingly, spatially relative terms such as “beneath”, “below”, “lower”, “under” “above”, and “upper” may be used to easily describe one element or feature's relationship with another element or feature.

In the specification, it will be understood that terms used to describe spaces, directions, etc. are intended to encompass different directions or viewpoints in addition to the spaces or directions shown in the drawings. For example, when a device or a component in the drawings is turned over, the device described as “below” may be otherwise oriented (e.g., rotated by 90 degrees or the opposite direction). For example, when a device or a component in the drawings is turned over, the device described as “above” may be otherwise oriented (e.g., rotated by 90 degrees or the opposite direction). Accordingly, the terms “below” and “above” may include both orientations of above and below. Also, a device or a component may be otherwise oriented and the spatially relative descriptors used herein should be interpreted accordingly.

In the specification, a process order or a method order in the description of a process or manufacturing method may be different from the described order. For example, two consecutively described processes or methods may be performed substantially at the same time or performed in an order opposite to the described order.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the specification, the terms “first”, “second”, and “third” may be used to describe specific components, and the terms “first”, “second”, and “third” may be used to distinguish one component from another.

When one component is referred to as “connected to” or “coupled to” another component, it may be directly connected to or coupled to the other component or one or more intervening component may be present therebetween.

Likewise, when one component is “electrically connected” to another component, the component and the other component may be directly and electrically connected, or may be indirectly and electrically connected through a conductive component.

Also, it will be understood that when one component is referred to as being “between” two components, it is the only component disposed between the two components or an intervening component other than the component is disposed between the two components.

The terminology used herein is for the purpose of describing particular embodiments only and is not intended to be limiting of the disclosure. The singular terms “a” and “an” used herein are intended to include the plural forms as well unless the context clearly indicates otherwise.

For example, the terms “comprises”, “comprising”, “includes”, and “including” specify the presence of the described feature, integer, step, operation, element, and/or component, but do not preclude the presence or addition of one or more other features, integers, steps, operations, elements, components, and/or groups thereof.

For example, the term “and/or” includes any and all combinations of one or more of the associated listed items. For example, the expression “A and/or B” indicates A, B, or A and B. The expression “at least one of” may be used to indicate one or more components among a plurality of components. For example, the expression “at least one of a, b, and c” or “at least one selected from the group consisting of a, b, and c” may indicate “a”, “b”, “c”, “a, b”, “b, c”, “a, c”, or “a, b, c”.

For example, the terms such as “substantially” and “about” and similar terms are used as terms of approximation rather than terms of degree, and may be intended to account for inherent deviations in measured or calculated values that would be recognized by one of ordinary skill in the art. For example, the use of the term “may” or “can” when describing embodiments may refer to embodiments disclosed in the specification.

Electronic or electric devices and/or other related devices or components (e.g., some of various modules) in embodiments described herein may be implemented by any suitable hardware, firmware (e.g., application-specific integrated circuit), software, or a combination of software, firmware, and hardware. In an embodiment, various components of these devices may be formed on one integrated circuit (“IC”) chip or separate IC chips. Furthermore, various components of these devices may be formed on a flexible printed circuit film, a tape carrier package (“TCP”), a printed circuit board (“PCB”), or formed on one substrate. Furthermore, various components of these devices may be processes or threads, running on one or more processors, in one or more computing devices, executing compute program instructions, and interacting with other system components for performing various functions described herein.

The computer program instructions are stored in a memory that may be implemented in a computing device using a standard memory device such as a random-access memory (“RAM”). The computer program instructions may also be stored in other non-transitory computer-readable media such as a compact disc read-only memory (“CD-ROM”) or a flash drive. Also, one of ordinary skill in the art should recognize that functions of various computing devices may be combined or integrated into a single computing device or that a function of a predetermined computing device may be distributed across one or more other computing devices without departing from the spirit and scope of the embodiments.

Hereinafter, a photomask pattern inspection method and system in an embodiment will be described in detail based on the above description.

For reference, a subject that performs the photomask pattern inspection method mentioned herein may be a computing device or a processor of the computing device, which will be described later.

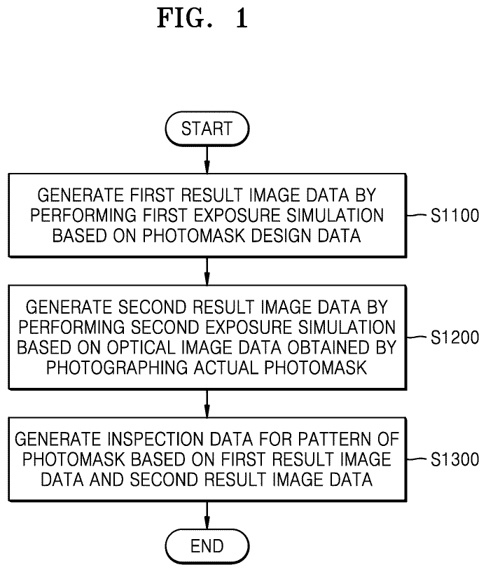

FIG. 1 is a flowchart schematically illustrating an embodiment of a photomask pattern inspection method.

As shown in FIG. 1, a photomask pattern inspection method in an embodiment may include generating first result image data by performing first exposure simulation based on photomask design data (operation S1100).

The photomask design data may be a design drawing of a photomask. In an embodiment, the photomask design data may be a graphic database system (“GDS”) or open artwork system interchange standard (“OASIS”) file, etc., and when a photomask includes a plurality of layers, the photomask design data may be a layer-specific design drawing, for example.

The first exposure simulation may be performed based on pre-input exposure condition data and the photomask design data. The pre-input exposure condition data may include conditions regarding the wavelength of a light source, the intensity of light, the area of exposure, etc., for example. The pre-input exposure condition data is a value input by a user and may be stored in a memory.

The first exposure simulation may virtually proceed with an exposure process on the photomask design data under a pre-input exposure condition. In an embodiment, a simulation tool for virtually proceeding with the exposure process may be existing commercial software such as Sysnopsis s-litho®, Prolith®, etc., for example. The first exposure simulation may derive a pattern state after an etching process after the exposure process.

In an embodiment, a first exposure result image may be a result value derived by the first exposure simulation, for example. The first exposure simulation performed on the photomask design data under a pre-input exposure condition may generate the first exposure result image generated according to a pattern of the photomask design data. The first result image data may be generated from the first exposure result image.

The photomask pattern inspection method in an embodiment may further include generating second result image data by performing second exposure simulation based on optical image data obtained by photographing an actual photomask (operation S1200).

The actual photomask is desired for the exposure process and may be used in an actual process. The actual photomask may be manufactured based on the photomask design data.

The optical image data may be obtained by an optical system device. In an embodiment, the optical system device may include a light source disposed on one side of the actual photomask, and an image sensor disposed in a direction opposite to the light source with respect to the actual photomask, for example. In an embodiment, the optical image data may be obtained by photographing the actual photomask by the optical system device.

The second exposure simulation may be implemented via the same software as that of the first exposure simulation. The second exposure simulation may be performed based on pre-input exposure condition data (hereinafter also referred to as input exposure condition data for convenience) and the optical image data.

An exposure condition input for the second exposure simulation may be the same as the exposure condition input for the first exposure simulation. In an embodiment, the pre-input exposure condition data may include conditions regarding the wavelength of a light source, the intensity of light, coherence of light, the area of exposure, etc., for example. The pre-input exposure condition data is a value input by a user and may be stored in a memory.

The second exposure simulation may virtually proceed with an exposure process on the optical image data under a pre-input exposure condition. In an embodiment, a simulation tool for virtually proceeding with the exposure process may be existing commercial software such as Sysnopsis litho®, Prolith®, etc., for example. The first exposure simulation may derive a pattern state after an etching process after the exposure process.

In an embodiment, a second exposure result image may be a result value derived by the second exposure simulation, for example. The second exposure simulation performed on the optical image data under a pre-input exposure condition may generate the second exposure result image generated according to a pattern of the optical image data. The second result image data may be generated from the second exposure result image.

The photomask pattern inspection method in an embodiment may further include generating inspection data for the actual photomask based on the first result image data and the second result image data (operation S1300).

The inspection data may be generated based on a differential image generated based on a first result image and a second result image, and may include information about whether a characteristic value derived from the differential image is greater than a preset threshold value.

In an embodiment, when the characteristic value derived from the differential image is greater than the preset threshold value, the inspection data may include information indicating that the actual photomask is in a defective state, for example. In an embodiment, when the characteristic value derived from the differential image is less than or equal to the preset threshold value, the inspection data may include information indicating that the actual photomask is in a normal state, for example.

Likewise, according to the photomask pattern inspection method in an embodiment, rapid and accurate inspection is possible during an operation of manufacturing the photomask. The photomask pattern inspection method in an embodiment may pre-perform the first exposure simulation or may perform the first exposure simulation in parallel with the second exposure simulation. While it is possible to perform inspection of a photomask pattern through an optical system device used to implement a projection optical system, when photomask pattern inspection is performed by only the device, errors may occur between an exposure result in an actual display manufacturing process and an exposure result during the inspection due to differences in lenses of the optical system device, light sources, mechanisms, actual exposure environments, etc. In order to minimize the occurrence of such errors and perform rapid inspection, the disclosure performs two simulations and performs pattern inspection through a differential image of two simulation results.

In addition, an organic light-emitting display device employs a current driving method, and the current driving method is more precise and better with respect to distribution than other driving methods. Therefore, precise inspection of a photomask pattern is important.

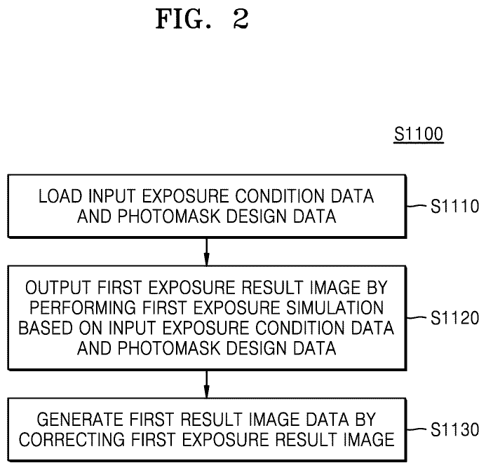

FIG. 2 is a flowchart schematically illustrating an operation of generating the first result image data by performing the first exposure simulation of FIG. 1.

As shown in FIG. 2, the generating of the first result image data by performing the first exposure simulation (operation S1100) may include loading input exposure condition data and the photomask design data.

The exposure condition data input by a user may be stored in a computing device described later. In addition, the photomask design data may also be stored in the computing device described later. Therefore, the generating of the first result image data by performing the first exposure simulation (operation S1100) may include loading the exposure condition data and the photomask design data, which are stored (or pre-input) in the computing device described later to perform the first exposure simulation.

The generating of the first result image data by performing the first exposure simulation (operation S1100) may further include outputting a first exposure result image by performing the first exposure simulation based on the input exposure condition data and the photomask design data (operation S1110), and generating the first result image data by correcting the first exposure result image (operation S1120).

The first exposure result image may be an image showing light that undergoes diffraction and interference according to the photomask design data, as a result of the simulation. The generating of the first result image data by correcting the first exposure result image (operation S1120) may include correcting the first exposure result image into a grayscale image having the same resolution as a resolution of the second result image data. In an embodiment, the first result image data may be obtained by converting the first exposure result image into the grayscale image, for example. In addition, the first result image data may be obtained by changing the resolution of the first exposure result image into a predetermined resolution (e.g., the same resolution as a resolution of the second result image data). The first result image data may be an aerial image of image data whose resolution is changed. The aerial image may have a size determined by a result of optimizing cable transmission speed, memory and storage high-speed read/write (“R/W”) capability, and/or central processing unit (“CPU”) computation complexity.

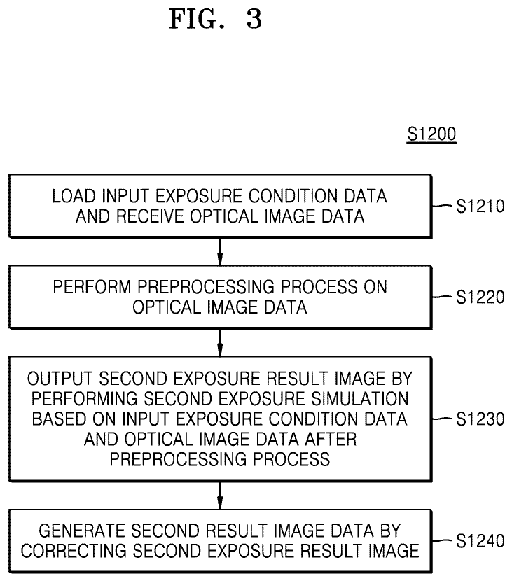

FIG. 3 is a flowchart schematically illustrating an operation of generating the second result image data by performing the second exposure simulation of FIG. 1.

As shown in FIG. 3, the generating of the second result image data by performing the second exposure simulation (operation S1200) may include loading input exposure condition data and receiving the optical image data (operation S1210).

The generating of the second result image data by performing the second exposure simulation (operation S1200) may further include performing a preprocessing process on the optical image data (operation S1220). The performing of the preprocessing process on the optical image data (operation S1220) may include obtaining a contour image from the optical image data and changing the resolution of the contour image to the resolution of the photomask design data.

In an embodiment, the preprocessing process may include at least some of processes including removing noise from optical image data, obtaining a contour image of optical image data, changing the resolution of a contour image to the resolution of photomask design data, and removing artifacts that occur when changing resolution (e.g., upscaling), for example.

The generating of the second result image data by performing the second exposure simulation (operation S1200) may further include, after the preprocessing process, outputting a second exposure result image by performing the second exposure simulation based on the pre-input exposure condition data and the optical image data (operation S1230), and generating the second result image data by correcting the second exposure result image (operation S1240).

The second exposure result image may be captured by the optical system device, and may be an image showing light that undergoes diffraction and interference according to a pattern of the actual photomask. The generating of the second result image data by correcting the second exposure result image (operation S1240) may include correcting the second exposure result image into a grayscale image having the same resolution as a resolution of the first result image data. In an embodiment, the second result image data may be obtained by converting the second exposure result image into the grayscale image, for example. In addition, the second result image data may be obtained by changing the resolution of the second exposure result image into a predetermined resolution (e.g., the same resolution as a resolution of the first result image data). The second result image data may be an aerial image of image data whose resolution is changed. The aerial image may have a size determined by a result of optimizing cable transmission speed, memory and storage high-speed R/W capability, and/or CPU computation complexity.

In addition, the correcting of the second exposure result image may be performed through a neural network model. In an embodiment, the neural network model used for image correction may be a generative adversarial network (“GAN”) model, a neutral style transfer model, etc. In some cases, the neural network model used for image correction may be a commercial model such as a rigorous simulation model, an inverse lithography technology (“ILT”) model, etc., for example. A method for improving resolution may be interpolation, image super resolution, etc.

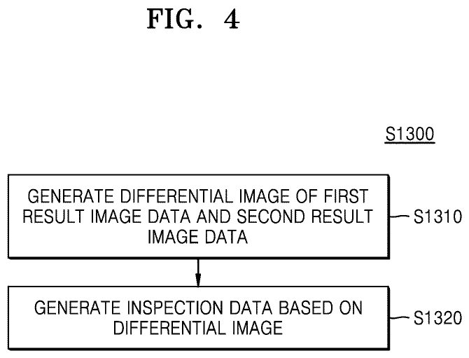

FIG. 4 is a flowchart schematically illustrating the operation of FIG. 1, of generating the inspection data.

As shown in FIG. 4, the generating of the inspection data for the actual photomask (operation S1300) may include generating a differential image of the first result image data and the second result image data (operation S1310).

The differential image may refer to a difference between the first result image data and the second result image data. In order to generate the differential image, the first result image data and the second result image data may be corrected to the same standard (e.g., same resolution, grayscale image, etc.).

The generating of the inspection data for the actual photomask (operation S1300) may further include generating the inspection data based on the differential image (operation S1320). The generating of the inspection data based on the differential image (operation S1320) may include defining the actual photomask as being in a defective state when a characteristic value (e.g., gray level, size level, etc.) derived from the differential image is greater than a preset threshold value, and defining the actual photomask as being in a normal state when the characteristic value (e.g., gray level, size level, etc.) is less than or equal to the preset threshold value.

The generating of the inspection data for the actual photomask (operation S1300) may include performing Blob analysis of differential pixels, which are greater than a threshold value set by a user, in a differential image, and generating or outputting the inspection data through a result of the Blob analysis. The Blob analysis may obtain size information, type information, etc., which are results of the Blob analysis of the differential image. A tool for the Blob analysis may be conventionally known software. The generating of the inspection data for the actual photomask (operation S1300) may include generating a defect file including the coordinates, serial number, etc., of a defective region in the differential image.

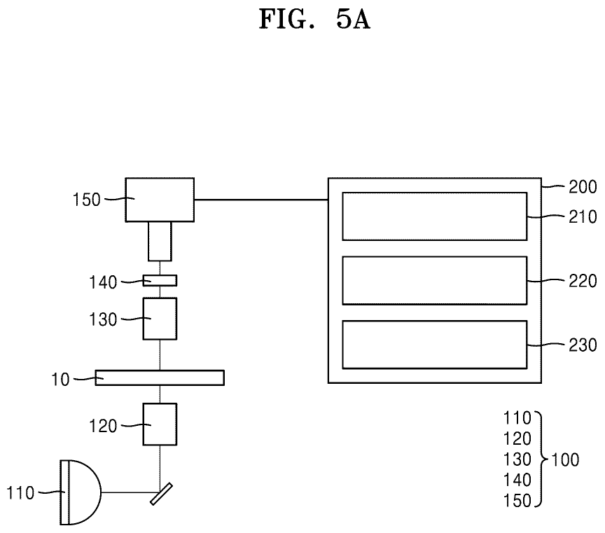

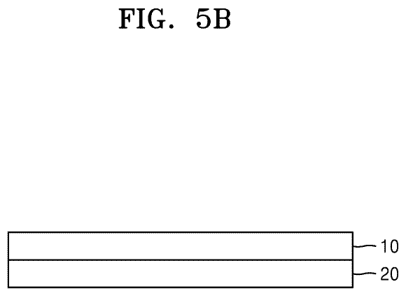

FIG. 5A is a view schematically illustrating an embodiment of a photomask pattern inspection system, and FIG. 5B is a view illustrating an actual photomask disposed on target substrate.

For reference, in the description of the photomask pattern inspection system of FIGS. 5A and 5B, description that are already provided above with reference to FIGS. 1 to 4 may not be provided.

As shown in FIG. 5A, the photomask pattern inspection system in an embodiment may include an optical system device 100 and a computing device 200.

The optical system device 100 may generate optical image data for an actual photomask. The optical system device 100 may include a light source 110, a condenser lens 120, an objective lens 130, a tube lens 140, and an automated optical inspection (“AOI”) camera 150.

In an embodiment, the light source 110 may be disposed on one side of an actual photomask 10, for example. The condenser lens 120 may be arranged between the light source 110 and the actual photomask. The light source 110 may irradiate light (e.g., ultraviolet rays) toward the condenser lens 120, and the light reflected through the condenser lens 120 may pass through the actual photomask and be directed to the objective lens 130. The light that has passed through the objective lens 130 and the tube lens 140 may be directed to the AOI camera 150, and the AOI camera 150 may generate the optical image data for the actual photomask. The generated optical image data may be transmitted to the computing device.

The computing device 200 may generate first result image data by performing first exposure simulation based on pre-stored photomask design data. The computing device 200 may generate second result image data by performing second exposure simulation based on the optical image data. The computing device 200 may generate inspection data for the actual photomask 10 based on the first result image data and the second result image data.

The computing device 200 may include a processor 210, a memory 220, and a data transceiver 230. The processor 210 may control other components by executing instructions stored in the memory 220. The processor 210 may perform instructions stored in the memory 220.

The processor 210 may be a component capable of performing calculations and controlling other devices. Mainly, the processor 210 may refer to a CPU, an application processor (“AP”), a graphics processing unit (“GPU”), etc. In addition, the CPU, the AP, or the GPU may include at least one core therein, and the CPU, the AP, or the GPU may operate by an operating voltage and a clock signal.

The processor 210 may process or provide a user with appropriate information or functions by processing signals, data, information, etc., which are input or output through the components described above, or by driving an application program stored in the memory 220.

The memory 220 stores data that supports various functions of the computing device 200. The memory 220 may store a plurality of application programs (or applications) running on the computing device 200, data for operating the computing device 200, and instructions.

The memory 220 may include at least one type of storage medium among a flash memory type, a hard disk type, a solid state disk (“SSD”) type, a silicon disk drive (“SDD”) type, a multimedia card micro type, a card type memory (e.g., secure digital (“SD”) or extreme digital (“XD”) memory, etc.), random access memory (“RAM”), static RAM (“SRAM”), read-only memory (“ROM”), electrically erasable programmable ROM (“EEPROM”), programmable ROM (“PROM”), magnetic memory, a magnetic disk, and an optical disk.

The data transceiver 230 may perform a wired communication function or wireless communication. The wireless communication may be communication (e.g., third generation (“3G”), long term evolution (“LTE”), fifth generation (“5G”), sixth generation (“6G”), etc.) using a wireless communication network that uses communication facilities previously installed by communication companies and frequencies of these communication facilities, or may be short-range communication such as Bluetooth®, Bluetooth® Low energy (“BLE”), beacon, radio frequency identification (“RFID”), near-field communication (“NFC”), infrared data association (“IrDA”), ultra wideband (“UWB”), zonal intercommunication global-standard (“ZigBee”), etc.

The computing device 200 may generate first result image data by performing first exposure simulation based on photomask design data. The first exposure simulation may be performed based on pre-input exposure condition data and the photomask design data. The pre-input exposure condition data may include conditions regarding the wavelength of the light source 110, the intensity of light, the coherence of light, the area of exposure, etc., for example. The pre-input exposure condition data is a value input by a user and may be stored in a memory.

In an embodiment, the first result image data may be a result value derived by the first exposure simulation, for example. The first exposure simulation performed on the photomask design data under a pre-input exposure condition may generate exposure image data generated according to a pattern of the photomask design data. The first result image data may be aerial image of the generated exposure image data.

The computing device 200 may generate second result image data by performing second exposure simulation based on optical image data obtained by photographing an actual photomask. The actual photomask 10 is desired for an exposure process and may be used in an actual process. The actual photomask 10 may be manufactured based on the photomask design data.

An exposure condition input for the second exposure simulation may be the same as the exposure condition input for the first exposure simulation. In an embodiment, the pre-input exposure condition data may include conditions regarding the wavelength of the light source 110 (e.g., ultraviolet wavelength band), the intensity of light, the coherence of light, the area of exposure, etc., for example. The pre-input exposure condition data is a value input by a user and may be stored in a memory.

The second exposure simulation may virtually proceed with an exposure process on the optical image data under a pre-input exposure condition. In an embodiment, the second result image data may be a result value derived by the second exposure simulation, for example. The second exposure simulation performed on the optical image data under the pre-input exposure condition may generate exposure image data generated according to a pattern of the optical image data. The second result image data may be aerial image of the generated exposure image data.

The computing device 200 may generate inspection data for the actual photomask based on the first result image data and the second result image data. The inspection data may be generated based on a differential image generated based on a first result image and a second result image, and may include information about whether a characteristic value derived from the differential image is greater than a preset threshold value.

In an embodiment, when the characteristic value derived from the differential image is greater than the preset threshold value, the inspection data may include information indicating that the actual photomask is in a defective state, for example. In an embodiment, when the characteristic value derived from the differential image is less than or equal to the preset threshold value, the inspection data may include information indicating that the actual photomask 10 is in a normal state, for example.

The computing device 200 may store the exposure condition data and the photomask design data. Therefore, the computing device 200 may load the input exposure condition data and the photomask design data in order to generate the first result image data by performing the first exposure simulation.

The computing device 200 may output a first exposure result image by performing the first exposure simulation based on the input exposure condition data and the photomask design data, and generate the first result image data by correcting the first exposure result image.

The first exposure result image may be an image showing light that undergoes diffraction and interference according to the photomask design data, as a result of the simulation. The computing device 200 may correct the first exposure result image into a grayscale image having the same resolution as a resolution of the second result image data. In an embodiment, the first result image data may be obtained by converting the first exposure result image into the grayscale image, for example. In addition, the first result image data may be obtained by changing the resolution of the first exposure result image into a predetermined resolution (e.g., the same resolution as a resolution of the second result image data). The first result image data may be an aerial image of image data whose resolution is changed. The aerial image may have a size determined by a result of optimizing cable transmission speed, memory and storage high-speed R/W capability, and CPU computation complexity.

The computing device 200 may load the input exposure condition data and receive the optical image data. The computing device 200 may perform a preprocessing process on the optical image data.

The preprocessing process performed by the computing device 200 may include a process of obtaining a contour image from the optical image data, and a process of changing the resolution of the contour image to the resolution of the photomask design data.

In an embodiment, the computing device 200 may perform a preprocessing process including at least some of processes including removing noise from optical image data, obtaining a contour image of optical image data, changing the resolution of a contour image to the resolution of photomask design data, and removing artifacts that occur when changing resolution (e.g., upscaling), for example.

The computing device 200 may output a second exposure result image by performing the second exposure simulation based on the pre-input exposure condition data and the optical image data after the preprocessing process, and generate the second result image data by correcting the second exposure result image.

The second exposure result image may be captured by the optical system device 100, and may be an image showing light that undergoes diffraction and interference according to a pattern of the actual photomask 10. The computing device 200 may correct the second exposure result image to a grayscale image having the same resolution as a resolution of the first result image data. In an embodiment, the second result image data may be obtained by converting the second exposure result image into the grayscale image. In addition, the second result image data may be obtained by changing the resolution of the second exposure result image into a predetermined resolution (e.g., the same resolution as a resolution of the first result image data), for example. The second result image data may be an aerial image of image data whose resolution is changed. The aerial image may have a size determined by a result of optimizing cable transmission speed, memory and storage high-speed R/W capability, and CPU computation complexity.

In addition, the computing device 200 may drive or use a neural network model in order to correct the second exposure result image. In an embodiment, the neural network model used for image correction may be a GAN model, a style transfer model, etc. In some cases, a function used for image correction may be a commercial model including rigorous simulation (FDTD, etc.) or compact (TCC, TMM, etc.) simulation, or a commercial model such as ILT, for example.

The computing device 200 may generate a differential image of the first result image data and the second result image data. The differential image may refer to a difference between the first result image data and the second result image data. In order to generate the differential image, the first result image data and the second result image data may be corrected to the same standard (e.g., same resolution, grayscale image, etc.).

The computing device 200 may generate inspection data based on the differential image. The computing device 200 may define the actual photomask as being in a defective state when a characteristic value (e.g., gray level, size level, etc.) derived from the differential image is greater than a preset threshold value, and define the actual photomask as being in a normal state when the characteristic value (e.g., gray level, size level, etc.) is less than or equal to the preset threshold value.

The computing device 200 may perform Blob analysis (and binarization) of differential pixels, which are greater than a threshold value set by a user, in a differential image, and generate or output the inspection data through a result of the Blob analysis. The Blob analysis may obtain size information, type information, etc., of an object detected in the differential image. A tool for the Blob analysis may be conventionally known software. The computing device 200 may generate a defect file including the coordinates, serial number, etc., of a Blob region in the differential image.

Likewise, according to the photomask pattern inspection system in an embodiment, rapid and accurate inspection is possible during an operation of manufacturing a photomask. While it is possible to perform inspection of a photomask pattern by only an optical system device, when photomask pattern inspection is performed by only the optical system device, errors may occur between an exposure result in an actual display manufacturing process and an exposure result during the inspection due to differences in lenses of the optical system device, light sources, mechanisms, etc. In order to minimize the occurrence of such errors and perform rapid inspection, the disclosure pre-performs the first exposure simulation or performs the first exposure simulation in parallel with the second exposure simulation through the computing device 200, and performs pattern inspection through a differential image of two simulation results.

In addition, an organic light-emitting display device employs a current driving method, and the current driving method is more precise and better with respect to distribution than other driving methods. Therefore, precise inspection of a photomask pattern is important.

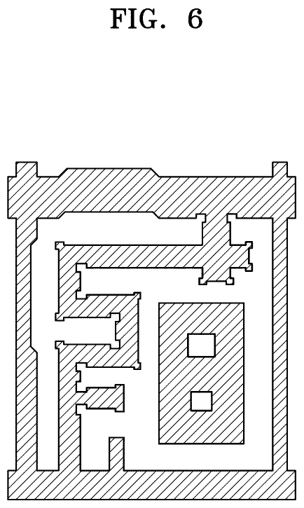

FIG. 6 is a view illustrating an embodiment of the photomask design data for performing the first exposure simulation.

Referring to FIG. 6, the photomask design data may be a design drawing of the actual photomask 10. The photomask design data may include a transmissive region through which light (e.g., ultraviolet rays) may pass during exposure, and a non-transmissive region through which light may not pass. The photomask design data may be a design drawing of an exposure pattern according to the shapes of the transmissive region and non-transmissive region.

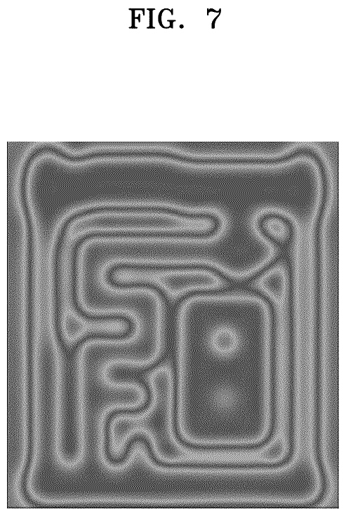

FIG. 7 is a view illustrating an embodiment of the first exposure result image generated based on the photomask design data of FIG. 6.

Referring to FIG. 7, the first exposure result image may be result data of the first exposure simulation. The first exposure result image may be result data of the first exposure simulation of a case where light (e.g., ultraviolet rays), which is under an exposure condition that has been pre-input into the photomask design data, is irradiated. The degree of diffraction, interference and transmission of light may be simulated according to a pattern of the photomask design data, and in the first exposure result image, the degree of diffraction, interference and transmission of light may be expressed by color, grayscale, etc.

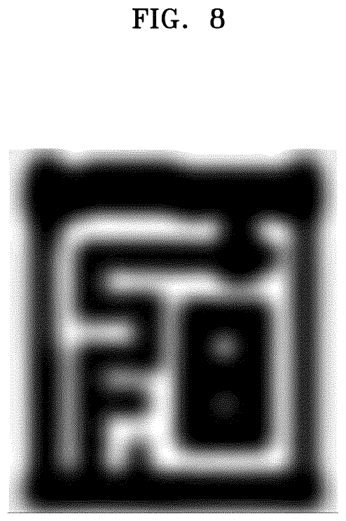

FIG. 8 is a view illustrating an embodiment of the first result image data generated based on the first exposure result image of FIG. 7.

Referring to FIG. 8, the first result image data may be an image obtained by correcting the first exposure result image. In an embodiment, the first result image data may be an image obtained by correcting the first exposure result image to have the same resolution as a resolution of the second result image data, for example. In an embodiment, the first result image data may be an image obtained by correcting the first exposure result image to a grayscale image, for example.

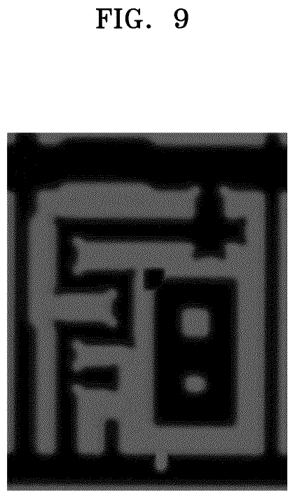

FIG. 9 is a view illustrating an embodiment of the optical image data obtained by photographing the actual photomask for performing the second exposure simulation.

Referring to FIG. 9, the optical image data is an image generated by the optical system device 100 and may be an image of the actual photomask 10. The actual photomask 10 is generated based on the photomask design data, and the optical image data may have a pattern that is the same as or similar to the photomask design data.

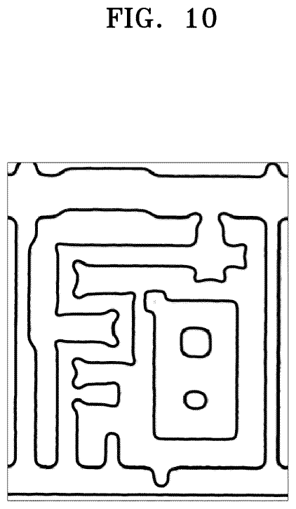

FIG. 10 is a view illustrating an embodiment of the contour image generated based on the optical image data of FIG. 9.

Referring to FIG. 10, the contour image is generated from the optical image data, and may include a boundary line for the pattern of the actual photomask 10. The contour image may correspond to the photomask design data.

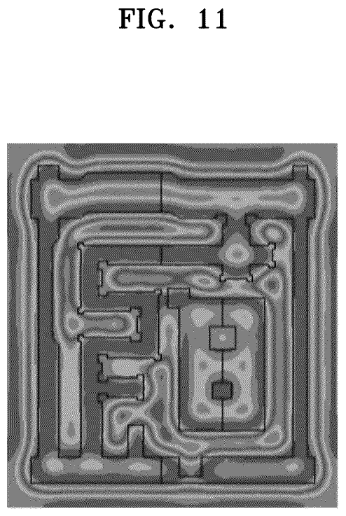

FIG. 11 is a view illustrating an embodiment of the second exposure result image generated based on the contour image of FIG. 10.

Referring to FIG. 11, the computing device 200 may derive pattern information including the transmissive region and non-transmissive region of the photomask based on the optical image data and the contour image. Therefore, the second exposure result image may be result data of the second exposure simulation. The second exposure result image may be result data of the second exposure simulation of a case where light (e.g., ultraviolet rays), which is under an exposure condition that has been pre-input into the pattern information derived based on the optical image data and the contour image, is irradiated.

In the second exposure result image, the degree of diffraction, interference and transmission of light may be simulated according to the pattern information derived based on the optical image data and the contour image, and in the second exposure result image, the degree of diffraction, interference and transmission of light may be expressed by color, grayscale, etc.

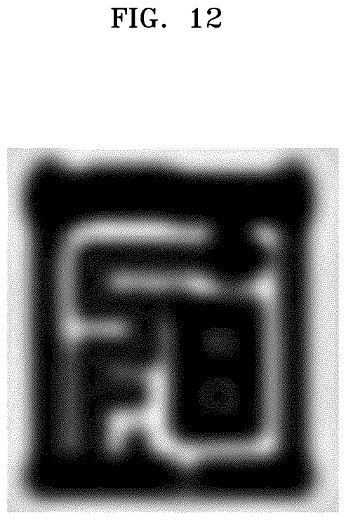

FIG. 12 is a view illustrating an embodiment of the second result image data generated based on the second exposure result image of FIG. 11.

Referring to FIG. 12, the second result image data may be an image obtained by correcting the second exposure result image. In an embodiment, the second result image data may be an image obtained by correcting the second exposure result image to have the same resolution as a resolution of the first result image data, for example. In an embodiment, the second result image data may be an image obtained by correcting the second exposure result image into a grayscale image, for example.

In addition, based on the descriptions provided above, a detailed description of a method of manufacturing a display device by a photomask pattern inspection method and system (hereinafter, also referred to as a method of manufacturing a display device), in an embodiment, is as follows.

The method of manufacturing the display device in an embodiment may include inspecting a pattern of an actual photomask by the computing device 200 of FIG. 5A, arranging the actual photomask 10 on a target substrate 20 of FIG. 5B when the pattern of the actual photomask 10 of FIG. 5A is in a normal state, and performing an exposure process on the target substrate 20 by the actual photomask 10. In an embodiment, the actual photomask 10 is directly disposed on the target substrate 20, but the disclosure is not limited thereto, and the actual photomask 10 may be space apart from the target substrate 20.

The normal state is information included in the inspection data, and may refer to a case where the characteristic value of the differential image is less than or equal to a preset threshold value.

The target substrate 20 may refer to a target on which a pattern is formed by the actual photomask 10. For convenience of explanation, the term “target substrate” may be used, but may refer to all components or layers of the display device, on which a pattern may be formed.

The exposure process may refer to part of an etching process for forming a desired pattern on the target substrate 20 by ultraviolet (“UV”) exposure.

The inspecting of the pattern of the actual photomask by the computing device may refer to the photomask pattern inspection method described with reference to FIGS. 1 to 4. Therefore, the description of the inspecting of the pattern of the actual photomask by the computing device is already provided above with reference to FIGS. 1 to 4 and thus is not provided.

In an embodiment, a photomask pattern inspection method and system capable of rapidly inspecting a photomask pattern and a method of manufacturing a display device by the same may be implemented. However, the scope of the disclosure is not limited by this effect.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A photomask pattern inspection method comprising:
generating first result image data by performing first exposure simulation based on photomask design data;
generating second result image data by performing second exposure simulation based on optical image data obtained by photographing an actual photomask; and
generating inspection data for the actual photomask based on the first result image data and the second result image data.

2. The photomask pattern inspection method of claim 1, wherein the photomask design data is design data for the actual photomask.

3. The photomask pattern inspection method of claim 1, wherein the generating the first result image data comprises generating the first result image data by performing the first exposure simulation based on pre-input exposure condition data and the photomask design data.

4. The photomask pattern inspection method of claim 3, wherein the generating the second result image data comprises generating the second result image data by performing the second exposure simulation based on the pre-input exposure condition data and the optical image data.

5. The photomask pattern inspection method of claim 4, wherein the generating the inspection data for the actual photomask comprises:
generating a differential image of the first result image data and the second result image data; and
generating the inspection data based on the differential image.

6. The photomask pattern inspection method of claim 5, wherein the generating the inspection data based on the differential image comprises:
in a case that a characteristic value derived from the differential image is greater than a preset threshold value, defining the actual photomask as being in a defective state; and
in a case that the characteristic value is less than or equal to the preset threshold value, defining the actual photomask as being in a normal state.

7. The photomask pattern inspection method of claim 1, wherein the generating the first result image data comprises:
loading input exposure condition data and the photomask design data;
outputting a first exposure result image by performing the first exposure simulation based on the input exposure condition data and the photomask design data; and
generating the first result image data by correcting the first exposure result image.

8. The photomask pattern inspection method of claim 7, wherein the generating the first result image data by correcting the first exposure result image comprises correcting the first exposure result image into a grayscale image having a same resolution as a resolution of the second result image data.

9. The photomask pattern inspection method of claim 1, wherein the generating the second result image data comprises:
loading input exposure condition data and receiving the optical image data;
performing a preprocessing process on the optical image data;
after the preprocessing process, outputting a second exposure result image by performing the second exposure simulation based on the input exposure condition data and the optical image data; and
generating the second result image data by correcting the second exposure result image.

10. The photomask pattern inspection method of claim 9, wherein the performing the preprocessing process on the optical image data comprises:
obtaining a contour image from the optical image data; and
changing a resolution of the contour image to a resolution of the photomask design data.

11. A photomask pattern inspection system comprising:
an optical system device configured to generate optical image data for an actual photomask; and
a computing device configured to:
generate first result image data by performing first exposure simulation based on pre-stored photomask design data;
generate second result image data by performing second exposure simulation based on the optical image data; and
generate inspection data for the actual photomask based on the first result image data and the second result image data.

12. The photomask pattern inspection system of claim 11, wherein the photomask design data is design data for the actual photomask.

13. The photomask pattern inspection system of claim 11, wherein the computing device is further configured to generate the first result image data by performing the first exposure simulation based on pre-input exposure condition data and the photomask design data.

14. The photomask pattern inspection system of claim 13, wherein the computing device is further configured to generate the second result image data by performing the second exposure simulation based on the pre-input exposure condition data and the optical image data.

15. The photomask pattern inspection system of claim 14, wherein the computing device is further configured to:
generate a differential image of the first result image data and the second result image data; and
generate the inspection data based on the differential image.

16. The photomask pattern inspection system of claim 15, wherein the computing device is further configured to:
define the actual photomask as being in a defective state in a case that a characteristic value derived from the differential image is greater than a preset threshold value; and
define the actual photomask as being in a normal state in a case that the characteristic value is less than or equal to the preset threshold value.

17. The photomask pattern inspection system of claim 11, wherein the computing device is further configured to:
load input exposure condition data and the photomask design data;
output a first exposure result image by performing the first exposure simulation based on the photomask design data; and
generate the first result image data by correcting the first exposure result image.

18. The photomask pattern inspection system of claim 17, wherein the first result image data is corrected into a grayscale image having a same resolution as a resolution of the second result image data.

19. The photomask pattern inspection system of claim 11, wherein the computing device is further configured to:
load input exposure condition data and receive the optical image data;
perform a preprocessing process on the optical image data, after the preprocessing process;
output a second exposure result image by performing the second exposure simulation based on the input exposure condition data and the optical image data; and
generate the second result image data by correcting the second exposure result image.

20. The photomask pattern inspection system of claim 19, wherein the computing device is further configured to:
obtain a contour image from the optical image data; and
change a resolution of the contour image to a resolution of the photomask design data.

21. A method of manufacturing a display device, the method comprising:
inspecting a pattern of an actual photomask by a computing device;
in a case that the pattern of the actual photomask is in a normal state, arranging the actual photomask on a target substrate;
performing an exposure process on the target substrate by the actual photomask,
wherein the inspecting the pattern of the actual photomask comprises:
generating first result image data by performing first exposure simulation based on photomask design data;
generating second result image data by performing second exposure simulation based on optical image data obtained by photographing the actual photomask; and
generating inspection data for the actual photomask based on the first result image data and the second result image data.

22. The method of claim 21, wherein the photomask design data is design data for the actual photomask.

23. The method of claim 21, wherein the generating the first result image data comprises generating the first result image data by performing the first exposure simulation based on pre-input exposure condition data and the photomask design data.

24. The method of claim 23, wherein the generating the second result image data comprises generating the second result image data by performing the second exposure simulation based on the pre-input exposure condition data and the optical image data.

25. The method of claim 24, wherein the generating the inspection data for the actual photomask comprises:
generating a differential image of the first result image data and the second result image data; and
generating the inspection data based on the differential image.
